(19) United States
(12) Patent Application Publication
(10) Pub. No.: US 2020/0027937 A1
(43) Pub. Date: Jan. 23, 2020

(54) LIGHT-EMITTING DEVICE AND ELECTRONIC APPARATUS

(71) Applicant: SEIKO EPSON CORPORATION, Tokyo (JP)

(72) Inventors: Takumi KODAMA, Chino-shi (JP); Takeshi KOSHIHARA, Matsumoto-shi (JP)

(73) Assignee: SEIKO EPSON CORPORATION, Tokyo (JP)

(21) Appl. No.: 16/512,794

(22) Filed: Jul. 16, 2019

(30) Foreign Application Priority Data
Jul. 17, 2018 (JP) 2018-133889

(51) Int. Cl. H01L 27/32; G09G 3/3241; H01L 51/52

(52) U.S. Cl. CPC H01L 27/3248; H01L 27/3276; G09G 2310/0278; H01L 51/5206; H01L 51/5221; G09G 3/3241

(57) ABSTRACT

A light-emitting device includes a display unit including a light-emitting portion and a non-light-emitting portion disposed around the light-emitting portion, and a driving line that is disposed in the display unit. The shorter a part of the driving line disposed in the light-emitting portion is, the longer a part of the driving line disposed in the non-light-emitting portion is.

The present application is based on, and claims priority from JP Application Serial Number 2018-133889, filed Jul. 17, 2018, the disclosure of which is hereby incorporated by reference herein in its entirety.

### BACKGROUND

### 1. Technical Field

The present disclosure relates to a light-emitting device and an electronic apparatus.

### 2. Related Art

An organic electroluminescence (EL) device including an organic light-emitting element (OLED; Organic Light-emitting Diode), for example, is known as a light-emitting device. The organic EL device is superior since it has a simpler structure because a lighting device is unnecessary compared to the liquid crystal device, it is thin and has flexibility when an organic light-emitting element and a driving circuit are formed on a plastic substrate, and it can realize a display device that is capable of responding to various shapes.

For example, JP-A-2016-81031 discloses a display device in which a display unit including an organic light-emitting element in a pixel is circular-shaped. The organic light-emitting element is configured to include an anode electrode, an organic light-emitting layer provided on the anode electrode, and a cathode electrode layer provided on the organic light-emitting layer. The organic light-emitting layer emits light by the data current supplied from the drive transistor with respect to the organic light-emitting element described above, and the video is displayed. A driving power supply line, a cathode power supply line, and a gate built-in circuit are each disposed in an arc shape along the circular-shaped display unit.

However, when the display unit is set to be circular-shaped as in the display device of JP-A-2016-81031, the display unit includes parts where the number of pixels attached to various signal wirings related to the display are different, and the capacitance and the resistance of the signal wirings differ depending on the positions of the pixels. Therefore, there is a possibility that differences occur in the emission luminance of the organic light-emitting element, for example, luminance unevenness may occur at the center part and the end part of the display unit. There is a problem in that luminance unevenness in such a self-emitting display device is easily recognized as display unevenness in comparison to a liquid crystal device.

### SUMMARY

A light-emitting device of the present application includes a display unit including a light-emitting portion in which a light-emitting pixel is disposed and a non-light-emitting portion disposed around the light-emitting portion, a driving circuit configured to drive the light-emitting pixel, and a driving line that is disposed in the display unit and that is coupled to the driving circuit, wherein an outline of the light-emitting portion is a shape different from a rectangle, and an outline of the display unit is a rectangle.

Another light-emitting device of the present application includes a display unit including a light-emitting portion in which a light-emitting pixel is disposed and a non-light-emitting portion disposed around the light-emitting portion, and a driving line that is disposed in the display unit and that is related to the light-emitting pixel, wherein an outline of the light-emitting portion is a shape different from a rectangle, and the shorter a part of the driving line disposed in the light-emitting portion is, the longer a part of the driving line disposed in the non-light-emitting portion is.

In the light-emitting device described above, the light-emitting pixel includes a first electrode and a second electrode, and a light-emitting function layer disposed between the first electrode and the second electrode, the second electrode is a common electrode disposed over the light-emitting portion and the non-light-emitting portion, and the non-light-emitting portion includes a second electrode contact portion disposed along the outline of the light-emitting portion.

In the light-emitting device described above, the second electrode contact portion may be disposed equidistantly from an outer edge of the light-emitting portion.

In the light-emitting device described above, the second electrode contact portion may include an electrode disposed in the same layer as the first electrode, and the electrode and the second electrode may be in contact with each other via the second electrode contact portion.

In the light-emitting device described above, the light-emitting function layer may be formed over the light-emitting portion and the non-light-emitting portion, and an outer edge of the light-emitting function layer may be located between the second electrode contact portion and an outer edge of the light-emitting portion.

In the light emitting device described above, the non-light-emitting portion may include a non-light-emitting dummy pixel between the second electrode contact portion and an outer edge of the light-emitting portion.

In the light emitting device described above, the dummy pixel may include, similarly to the light-emitting pixel, the first electrode, the second electrode, and the light-emitting function layer, and may include an insulating film between the first electrode and the light-emitting function layer.

In the light emitting device described above, the light emitting device may include a sealing film disposed on the display unit and covering at least the light-emitting portion and the second electrode contact portion, and a color filter disposed, on the sealing film, corresponding to the light-emitting pixel.

An electronic apparatus according to the present disclosure includes the light-emitting device described above.

### BRIEF DESCRIPTION OF THE DRAWINGS

FIG. 1 is a schematic plan view illustrating a configuration of a light-emitting device.

FIG. 2 is a schematic cross-sectional view illustrating a structure of the light-emitting device.

FIG. 3 is a circuit block diagram illustrating an electrical configuration of the light-emitting device.

FIG. 4 is an equivalent circuit diagram illustrating a pixel circuit in a light-emitting pixel.

FIG. 5 is a schematic plan view illustrating a configuration of a driving line in a display unit.

FIG. 6 is a schematic plan view illustrating a configuration of the display unit.

FIG. 7 is a schematic plan view illustrating a configuration of a color filter in the light-emitting pixel.

FIG. 8 is a partial cross-sectional view schematically illustrating a structure of a light-emitting panel.

FIG. 9 is an enlarged cross-sectional view illustrating a light resonance structure of light-emitting pixels of the light-emitting panel.

FIG. 10 is a perspective view illustrating a head-mounted display serving as an electronic apparatus.

FIG. 11 is a schematic plan view illustrating a configuration of a light-emitting device in the head-mounted display.

FIG. 12 is a schematic plan view illustrating a display unit of a modified example of the light-emitting device.

FIG. 13 is a schematic plan view illustrating a display unit of a modified example of the light-emitting device.

FIG. 14 is a schematic plan view illustrating a display unit of a modified example of the light-emitting device.

FIG. 15 is a schematic plan view illustrating a configuration of light-emitting pixels of a modified example.

### DESCRIPTION OF EXEMPLARY EMBODIMENTS

Exemplary embodiments of the present disclosure will be described below with reference to the accompanying drawings. Note that, in the drawings referred to below, the parts described are illustrated in an enlarged or reduced state as appropriate so that those parts can be easily recognized.

### First Exemplary Embodiment

Light-Emitting Device

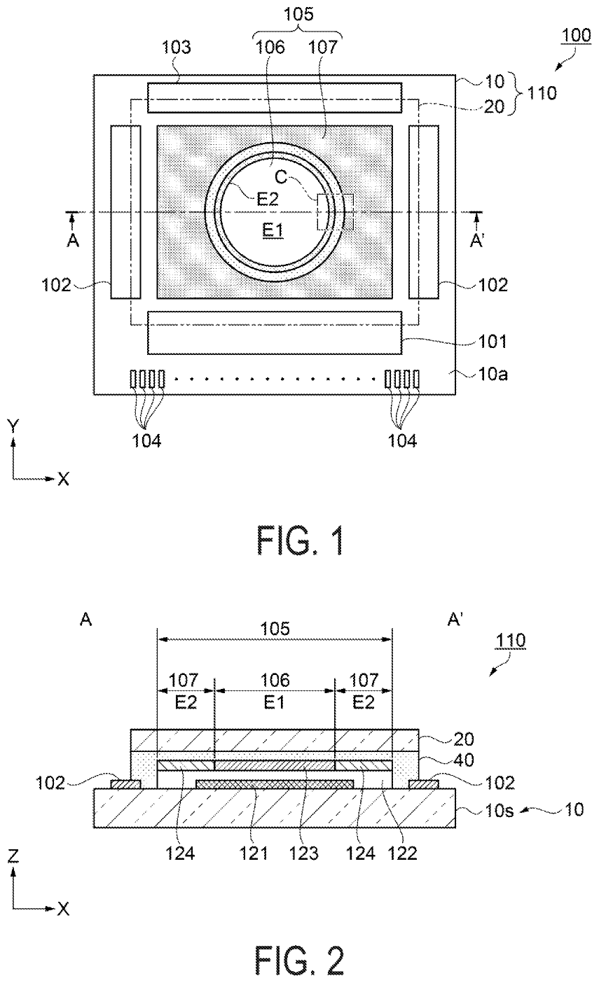

A basic configuration of a light-emitting device according to the present exemplary embodiment will be described with reference to FIG. 1 and FIG. 2. FIG. 1 is a schematic plan view illustrating a configuration of the light-emitting device, and FIG. 2 is a schematic cross-sectional view illustrating a structure of the light-emitting device. Note that, line A-A′ illustrated in FIG. 1 is a line segment crossing the center of a light-emitting portion of the light-emitting device.

As illustrated in FIG. 1 and FIG. 2, the light-emitting device 100 of the present exemplary embodiment includes a light-emitting panel 110 including an element substrate 10 and a counter substrate 20 that is light-transmissive and is disposed opposite the element substrate 10. A display unit 105 including a light-emitting portion 106 and a non-light-emitting portion 107 disposed around the light-emitting portion 106 is disposed in the element substrate 10. A detailed configuration of the display unit 105 is described later, but a plurality of light-emitting pixels is disposed in the light-emitting portion 106. The light-emitting pixel includes a light-emitting element, and a data line driving circuit 101 and a scanning line driving circuit 102 are disposed in the periphery of the display unit 105 as a driving circuit for driving the light-emitting element. The light-emitting device 100 is an active drive type in which the light-emitting elements disposed in the light-emitting pixels can be individually driven.

The element substrate 10 is slightly larger than the counter substrate 20, and a plurality of external connection terminals 104 for connecting to an external driving circuit are aligned in a terminal part 10a, which is a side part of the element substrate 10 protruding from the counter substrate 20. The data line driving circuit 101 is disposed between the plurality of external connection terminals 104 and the display unit 105. The scanning line driving circuit 102 is disposed between the display unit 105 and each of the two opposing side parts orthogonal to the terminal part 10a of the element substrate 10. An inspecting circuit 103 is disposed between the side part of the element substrate 10 opposite the terminal section 10a and the display 105. The inspecting circuit 103 is configured to be capable of detecting a data signal supplied to each of the plurality of light-emitting pixels from the data line driving circuit 101, and inspecting whether each of the plurality of light-emitting pixels is operating normally. The data line driving circuit 101 and the scanning line driving circuit 102 as the driving circuit, and an inspecting circuit 103 are referred to as peripheral circuits.

In the present exemplary embodiment, a region in which the light 106 is disposed may be referred to as a light-emitting region E1, and a region in which the non-light-emitting portion 107 is disposed so as to surround the light-emitting portion 106 may be referred to as a non-light-emitting region E2. In the present exemplary embodiment, an outline of the display unit 105 is a rectangle (rectangular shape), and an outline of the light-emitting portion 106 (light-emitting region E1) is a circle having a shape different from a rectangle. The light-emitting portion 106 is disposed substantially at the center of the display unit 105, and the non-light-emitting portion 107 (non-light-emitting region E2) is disposed so as to surround the light-emitting portion 106.

Hereinafter, a direction in which the plurality of external connection terminals 104 are aligned in the terminal part 10a of the element substrate 10 will be described as an X direction, and a direction orthogonal to the X direction on the element substrate 10 will be described as the Y direction. Further, a direction that is orthogonal to the X direction and the Y direction and oriented from the element substrate 10 toward the counter substrate 20 will be described as a Z direction. Additionally, a view taken along the Z direction from the counter substrate 20 side will be called a plan view.

As illustrated in FIG. 2, the element substrate 10 and the counter substrate 20 are bonded via a filler 40 made of light-transmissive material, for example, an epoxy-based resin. The filler 40 is disposed so as to cover the display unit 105 and to partially overlap on the peripheral circuit including the scanning line driving circuit 102.

An element portion 121 including a plurality of light-emitting elements, a sealing film 122 covering the element portion 121, and a color filter 123 disposed corresponding to the light-emitting pixels on the sealing film 122 are disposed in the element substrate 10. Further, a light shielding portion 124 is disposed on the sealing film 122 in a non-light-emitting portion 107 (non-light-emitting region E2) surrounding the light-emitting portion 106 (light-emitting region E1). The element portion 121 is disposed so as to overlap with the color filter 123, and partly overlaps with the light shielding portion 124, in a plan view. That is, light emitted from the light-emitting element of the element portion 121 is emitted from the counter substrate 20 side through the sealing film 122 and the color filter 123. The display unit 105 includes the element portion 121, the sealing film 122, the color filter 123, and the light shielding portion 124, and details of these configurations will be described later. Note that, in the present exemplary embodiment, a semiconductor substrate such as a silicon substrate is used as a base material of the element substrate 10 in which the element portions 121 are formed.

In this light-emitting panel 110, a driving line for electrically connecting the data line driving circuit 101 and the scanning line driving circuit 102 as the driving circuit for driving the light-emitting element in the light-emitting portion 106 is disposed in the display unit 105. A detailed configuration of the driving line will be described later.

Electrical Configuration of Light-Emitting Device

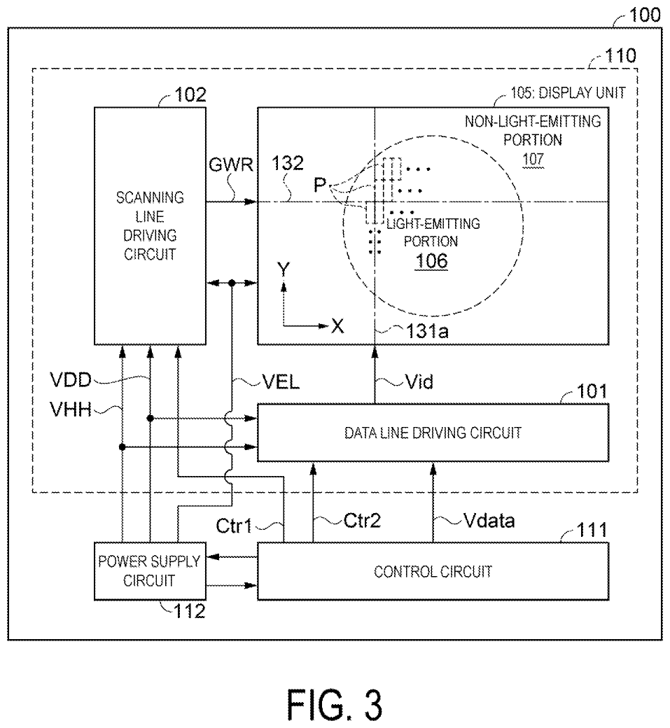

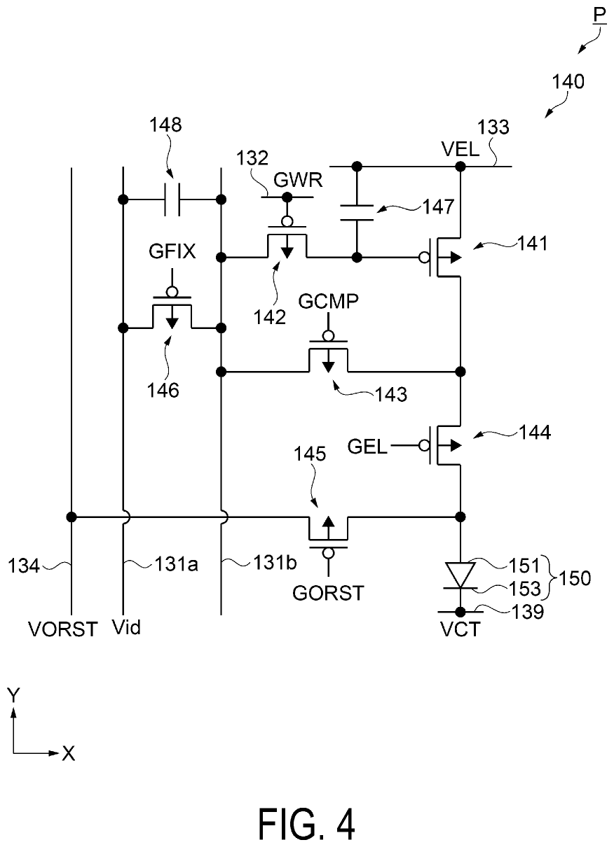

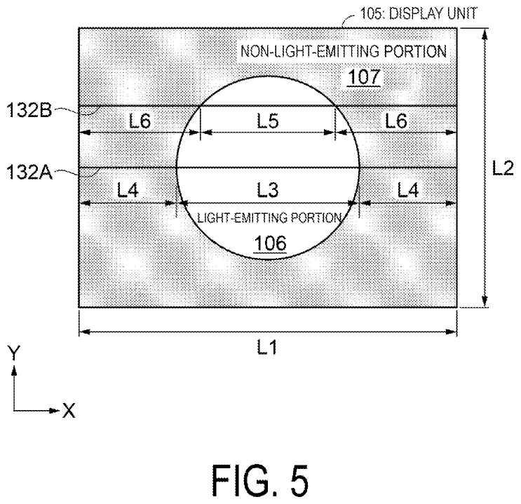

Next, an electrical configuration of the light-emitting device 100 will be described with reference to FIG. 3 and FIG. 5. FIG. 3 is a circuit block diagram illustrating an electrical configuration of the light-emitting device, FIG. 4 is an equivalent circuit diagram illustrating a pixel circuit in the light-emitting pixel, and FIG. 5 is a schematic plan view illustrating a configuration of the driving line in the display unit.

As illustrated in FIG. 3, the light-emitting device 100 includes a display unit 105 including a light-emitting portion 106 and a non-light-emitting portion 107, a data line driving circuit 101, and a scanning line driving circuit 102. Further, the light-emitting device includes a control circuit 111 and a power supply circuit 112 which are serving as the external driving circuit coupled to the light emission panel 110 via the external connection terminal 104 described above (see FIG. 1). Note that in the circuit block diagram of FIG. 3, the inspecting circuit 103 illustrated in FIG. 1 is omitted.

Light-emitting pixels P are disposed in the light-emitting portion 106 across the X direction and the Y direction. The light 106 is circular, and when the X direction is the row direction and the Y direction is the column direction, up to n light-emitting pixels P are aligned in the row direction and up to m light-emitting pixels P are aligned in the column direction. Accordingly, in the display unit 105, driving lines for supplying various signals are disposed corresponding to the plurality of light-emitting pixels P in n columns×m rows aligned in the light-emitting portion 106. Further, in the present exemplary embodiment, three light-emitting pixels P aligned in the X direction (row direction) are serving as one display unit pixel configured to obtain the light emission of red (R), green (G), and blue (B) from the display unit pixel. This enables color display in the light-emitting portion 106.

The control circuit 111 supplies a control signal Ctr1 to the scanning line driving circuit 102 and a control signal Ctr2 to the data line driving circuit 101. Further, the control circuit 111 supplies image data Vdata corresponding to the light-emitting pixels P in each row of the light-emitting portion 106 to the data line driving circuit 101 for each row. Further, the control circuit 111 controls generation of various power supply voltages by the power supply circuit 112.

The control signal Ctr1 is a pulse signal for controlling the scanning line driving circuit 102 and includes a vertical synchronization signal, a horizontal synchronization signal, a clock signal, and an enable signal. The control signal Ctr2 includes a horizontal synchronization signal, a sampling signal, a dot clock signal, a latch pulse signal, and an enable signal for controlling the data line driving circuit 101. The image data Vdata is a digital signal corresponding to a gradation value (gray level) for each of the light-emitting pixels P in a row selected by a scanning signal GWR transmitted from the scanning line driving circuit 102 to the light-emitting portion 106.

The scanning line driving circuit 102 generates, based on the control signal Ctr1, the scanning signal GWR for sequentially selecting and operating pixel circuits 140 (see FIG. 4) for each row of light-emitting pixels P in each frame period defined by the vertical synchronization signal. The scanning signal GWR is supplied to the pixel circuit 140 of the light-emitting portion 106 via a scanning line 132 disposed in the display unit 105 and extending in the X direction. Note that, in addition to the scanning signal GWR, the scanning line driving circuit 102 generates various control signals to be supplied to the pixel circuit 140 for each row, but the control signals are omitted in FIG. 3. Although a detailed configuration of the scanning line driving circuit 102 is not illustrated in FIG. 3, a known circuit configuration may be employed, and is configured to include, for example, a shift register, a latch circuit, a demultiplexer, and the like.

The data line driving circuit 101 generates, based on the image data Vdata and the control signal Ctr2, an n-column of the data signal Vid corresponding to a gradation value of each of the light-emitting pixels P in the row selected by the scanning line driving circuit 102 for each horizontal scanning period. The data signal Vid is supplied to the pixel circuit 140 of the light-emitting portion 106 via a first data line 131a disposed in the display unit 105 and extending in the Y direction. Although the detailed configuration of the data line driving circuit 101 is not illustrated in FIG. 3, a known circuit configuration may be employed, including, for example, a shift register, a data latch circuit, a line latch circuit, a D/A (digital/analog) conversion circuit, a demultiplexer, and the like.

The power supply circuit 112 generates and supplies the various power supply voltages required for driving the light-emitting portion 106 (pixel circuit 140 of the light-emitting pixel P), the data line driving circuit 101, the scanning line driving circuit 102, and the control circuit 111. Further, the power supply circuit 112 not only supplies the power supply potential related to driving to the data line driving circuit 101, but also supplies a plurality of levels of gradation reference voltage corresponding to the gradation value of the light-emitting pixel P.

The power supply potential generated by the power supply circuit 112 is VDD, VHH, and VEL. VDD is a low voltage (for example, 1.8V) for logic. VHH is a high voltage (for example, 5.5V) for logic and amplifier. VEL is a supply voltage (for example, 5.5V as VHH) to the pixel circuit 140 (see FIG. 4). Note that, in addition to the above, the power supply circuit 112 generates a reference potential VSS, a cathode potential VCT of the pixel circuit 140, a reset voltage VORST (see FIG. 4), and the like, which are omitted from FIG. 3.

As illustrated in FIG. 4, the pixel circuit 140 in the light-emitting pixels P is disposed corresponding to the intersection between the first data line 131a extending in the Y direction and the scanning line 132 and the power supply line 133 extending in the X direction, and is configured to include six P-type Metal-Oxide Semiconductor Field-Effect Transistors (MOSFET) 141 to 146, two storage capacitors 147 and 148, and a light-emitting element 150. Hereinafter, for convenience of explanation, the six P-type MOSFET are referred to as a first transistor 141, a second transistor 142, a third transistor 143, a fourth transistor 144, a fifth transistor 145, and a sixth transistor 146. A second data line 131b and a potential line 134 are disposed in parallel with the first data line 131a. A reset voltage VORST is supplied from the power supply circuit 112 to the potential line 134. The first data line 131a extending in the Y direction and the scanning line 132 extending in the X direction are an example of a driving line in the present disclosure.

The first transistor 141 functions as a drive transistor, and one of the source or the drain is coupled to the power supply line 133, and the other is coupled to one of the source or drain of the third transistor 143 and the fourth transistor 144. Further, the gate of the first transistor 141 is coupled to one of the source or drain of the second transistor 142. A storage capacitor 147 is connected between the gate of the first transistor 141 and the power supply line 133. A power supply potential VEL is supplied from the power supply circuit 112 as described above to the power supply line 133. That is, the storage capacitor 147 functions as a retention capacitor of the gate potential of the first transistor 141 with respect to the power supply potential VEL.

The second transistor 142 functions as a write transistor, and the other one of the source or drain is coupled to the second data line 131b. The second transistor 142 is controlled in selection/non-selection by the scanning signal GWR supplied to the gate via the scanning line 132. Note that, the scan line 132 is coupled to the scanning line driving circuit 102.

The third transistor 143 functions as a threshold compensation transistor, and is controlled in ON/OFF by a control signal GCMP supplied to the gate.

The fourth transistor 144 functions as a current supply control transistor, and one of the source or the drain is coupled to the other one of the source or drain of the first transistor 141 and one of the source or drain of the third transistor 143. The other one of the source or drain of the fourth transistor 144 is coupled to an anode electrode (anode) 151 as the first electrode of the light-emitting element 150. A control signal GEL is supplied to the gate to control ON/OFF of the fourth transistor 144. For example, by the fourth transistor 144, it is possible to prevent current from flowing to the light-emitting element 150 and causing unintentional emission after power up of the light-emitting device 100.

The fifth transistor 145 functions as a reset transistor, and one of the source or the drain is coupled to the other one of the source or drain of the fourth transistor 144. The other one of the source or drain of the fifth transistor 145 is coupled to the potential line 134. A control signal GORST is supplied to the gate to control ON/OFF of the fifth transistor 145. As described above, the reset voltage VORST is supplied from the power supply circuit 112 to the potential line 134.

One of the source or the drain of the sixth transistor 146 is coupled to the first data line 131a, and the other one is coupled to the second data line 131b. A control signal GFIX is supplied to the gate to control ON/OFF of the sixth transistor 146. The data signal Vid is supplied to the first data line 131a from the data line driving circuit 101. A storage capacitor 148 is connected between the first data line 131a and the second data line 131b. That is, the storage capacitor 148 functions as a transfer capacitor of the data signal Vid transferred from the first data line 131a to the second data line 131b by the sixth transistor 146.

Note that, although not illustrated in detail in FIG. 4, the number dividing the total number m of light-emitting pixels in the Y direction of the display unit 105 by q, which is an arbitrary number, is disposed for each row. That is, by controlling the sixth transistor 146 as the number of pixel circuits 140 attached to one second data line 131b is set to q, which is an arbitrary number, the data signal Vid can be supplied to the pixel circuit 140 from the first data line 131a for each of the q light-emitting pixels P grouped in the column direction. For example, when the total number of light-emitting pixels m is 720 and q is 90, 90 pixel circuits 140 are attached to one second data line 131b, and eight second data lines 131b are disposed per row in the X direction.

As described above, the anode electrode 151 of the light 150 is coupled to the other one of the source or drain of the fourth transistor 144 and one of the source or drain of the fifth transistor 145. A cathode electrode 153 as a second electrode provided across the plurality of light-emitting elements 150 and serving as a common electrode is coupled to a cathode electrode wiring 139. The cathode electrode potential VCT is supplied to the cathode wiring 139 from the power supply circuit 112. The cathode electrode potential VCT may be a reference potential VSS (for example, 0 V as ground potential).

The light-emitting element 150 is an organic light-emitting diode having a light-emitting function layer between the anode electrode 151 as a first electrode and the cathode electrode 153 as the second electrode. When a current flows between the anode 151 and the cathode 153, excitons (a state where a hole and an electron bind to each other under Coulomb force) are formed by the holes injected from the anode 151 and the electrons injected from the cathode 153, and when the excitons decay (that is, when the holes and electrons recombine), a part of the resulting energy is emitted as fluorescence or phosphorescence. In the present exemplary embodiment, the configuration is such that white light is emitted from the light-emission function layer.

The first transistor 141 and the light-emitting element 150 are connected in series between the power supply line 133 and the cathode wiring 139. The first transistor 141 is a drive transistor, and controls the current flowing in the light-emitting element 150 in accordance with the gate potential. In other words, the first transistor 141 functions as a current source. The ON/OFF of the light-emitting element 150 is controlled by the fourth transistor 144, and the amperage of current flowing in the light-emitting 150 is controlled by the first transistor 141. The second transistor 142, the third transistor 143, the fourth transistor 144, and the sixth transistor 146 are used to control the potential of the node in the pixel circuit 140. As a result, the configuration is such that the light emission corresponding to the predetermined gradation value (gray level) is obtained from the light-emitting 150 at a predetermined timing based on the data signal Vid supplied from the data line driving circuit 101 via the first data line 131a to the pixel circuit 140. Note that the pixel circuit 140 for the driving of the light-emitting element 150 is not limited to a configuration including the first transistor 141 to the sixth transistor 146. For example, a configuration may be adopted in which the second transistor 142 and the third transistor 143 are coupled to the first data line 131a by deleting the second data line 131b, the sixth transistor 146, and the storage capacitor 148. The light-emitting element 150 emits light at a luminance corresponding to the current flowing to the light-emitting element 150, thus, the configuration may include a drive transistor serving as a current source, in order to perform high accuracy gradation control.

Next, the configuration of the driving lines in the display unit 105 will be described with reference to FIG. 5. As illustrated in FIG. 5, the display unit 105 is a rectangle in which the length L1 in the X direction of the outline is longer than the length L2 in the Y direction. The display unit 105 includes the light-emitting portion 106 and the non-light-emitting portion 107, and the light-emitting portion 106 having a circular outline is located at the center of the display unit 105 in the X direction and the Y direction. A description will be given of a scanning line 132 as an example of a driving line. As described above, the scanning line 132 is disposed extending in the X direction corresponding to each light-emitting element 150 of the plurality of light-emitting pixels P disposed in the light-emitting portion 106. Therefore, the length in the X direction of the scanning line 132 in the display unit 105 is L1. For example, a scanning line 132A passing through the center of the light-emitting portion 106 (in other words, the center of the display unit 105) has a longest length L3 in the light-emitting portion 106, and a length in the non-light-emitting portion 107 is the shortest 2×L4. The length L1 in the X direction of the scanning line 132A forms a relationship of L1=L3+2×L4. In contrast, the scanning line 132B located at a position offset in the Y direction from the center of the light 106 has a length L5 less than L3 in the light-emitting portion 106, and has a length 2×L6 greater than 2×L4 in the non-light-emitting portion 107. The length L1 of the scanning line 132B in the X direction at a position outside the center of the light-emitting portion 106 forms a relationship of L1=L5+2×L6.

That is, since the display unit 105 is a rectangle, the length of the scanning line 132 extending in the X direction is constant at L1, and the light-emitting portion 106 has a circle shape different from the rectangle, thus, the shorter the length of the part of the scanning line 132 in the light-emitting portion 106 is, the longer the length of the part of the scanning line 132 in the non-light-emitting portion 107 becomes. Although not illustrated in FIG. 5, a configuration of the first data line 131a as the driving line in the display unit 105 is the same as the scanning line 132, since the display unit 105 is a rectangle, the length of the first data line 131a extending in the Y direction is constant at L2, and the light-emitting portion 106 has a circle shape different from the rectangle, thus, the shorter the length of the part of the first data line 131a in the light-emitting portion 106 is, the longer the length of the part of the first data line 131a in the non-light-emitting portion 107 becomes.

Note that a relative position of the light-emitting portion 106 with respect to the display unit 105 is not limited to being located at the center of the display unit 105. In this case as well, technical features related to the length of the driving line described above in the light-emitting portion 106 and the non-light-emitting portion 107 are also included.

Configuration of Display Unit

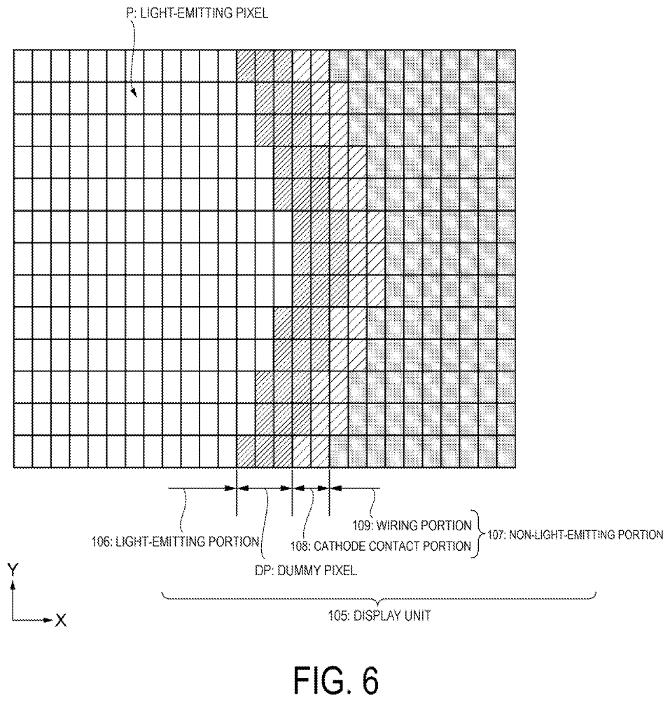

Next, a configuration of the display unit 105 will be described with reference to FIG. 6. FIG. 6 is a schematic plan view illustrating a configuration of the display unit. Note that, FIG. 6 is an enlarged plan view of a quadrangular region C surrounded by a double dot dash line illustrated in the display unit 105 in FIG. 1.

As illustrated in FIG. 6, the display unit 105 is configured to include the light-emitting portion 106 and the non-light-emitting portion 107. In the light-emitting portion 106, a plurality of rectangular light-emitting pixels P in which a length of a side portion in the Y direction is longer than a length of a side portion in the X direction, are aligned in the X direction and the Y direction. The non-light-emitting portion 107 is configured to include dummy pixels DP, a cathode contact portion 108 as a second electrode contact portion, and a wiring portion 109. The outline of the light 106 is circular as illustrated in FIG. 1, but when the light-emitting pixels P are expanded to a recognizable state as illustrated in FIG. 6, there is a step due to the shape of the light-emitting pixels P on the outer periphery of the light-emitting portion 106.

The dummy pixels DP are disposed so as to surround a light-emitting portion 106 which apparently has a circular outline. In addition, the cathode contact portion 108 is disposed outside the dummy pixels DP. That is, outlines of the dummy pixels DP and the cathode contact portions 108 are also apparently circular. The outside of the cathode contact portion 108 is serving as a wiring portion 109 in which wiring is disposed related to the light-emitting pixels P, the dummy pixels DP, and the cathode contact portion 108.

In the present exemplary embodiment, of course the dummy pixels DP, and additionally the cathode contact portion 108 adjacent to the dummy pixels DP, are configured to imitate the structure of the light-emitting pixels P. The specific structure of the dummy pixels DP and the cathode contact portion 108 will be described later.

In FIG. 6, the number of dummy pixels DP disposed on the outer peripheral side of the light-emitting portion 106 is three, but the number is not limited to this. It is sufficient that at least one dummy pixel DP is disposed along the outer periphery of the light-emitting portion 106. In addition, the cathode contact portion 108 disposed in the outer peripheral side of the dummy pixels DP is two in terms of the planar size of the light-emitting pixel P, but is not limited to this. It is sufficient that the cathode contact portion 108 corresponding to at least one of the light-emitting pixels P is disposed along the outer circumference of the dummy pixel DP. In the present exemplary embodiment, the cathode contact portion 108 is disposed at equal distances with respect to the light-emitting pixels P located at the outer edge of the light-emitting portion 106 with the dummy pixels DP interposed therebetween. In other words, the distance from the center of the circular light-emitting portion 106 to the cathode contact portion 108 is equidistant in the X direction and the Y direction.

Light-Emitting Pixels and Color Filters

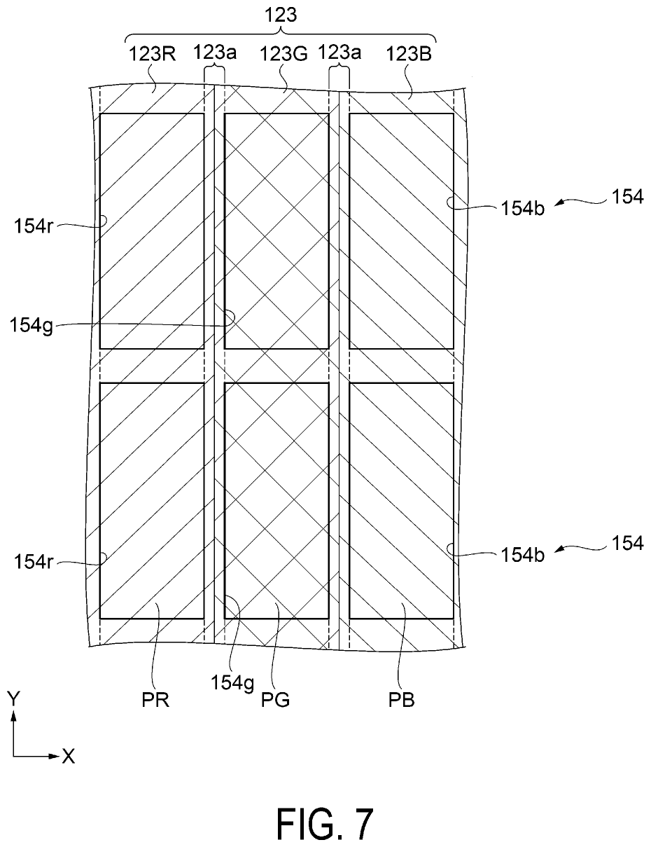

Next, a relationship between the light-emitting pixel P and the color filter will be described with reference to FIG. 7. FIG. 7 is a schematic plan view illustrating the configuration of color filters in the light-emitting pixels. The light-emitting device 100 of the present exemplary embodiment achieves color display by including the color filter 123 and the light-emitting element 150 in which white light emission is obtained in the light-emitting pixel P. Note that, the color filter 123 is disposed corresponding to the light-emitting pixels P that is in the light-emitting region E1 of the element portion 121 as illustrated in FIG. 2.

As illustrated in FIG. 7, colored layers selected from three colors: red (R), green (G), and blue (B) are disposed in the light-emitting pixels P aligned in the X direction and the Y direction. Specifically, the color filter 123 of the present exemplary embodiment is configured to include three color colored layers 123R, 123G, and 123B in a striped method. Each of the three colored layers 123R, 123G, and 123B is disposed extending in the Y direction corresponding to the light-emitting pixels P aligned in the Y direction. Hereinafter, the light-emitting pixel P in which the red colored layer 123R is disposed may be referred to as a light-emitting pixel PR, the light-emitting pixel P in which the green colored layer 123G is disposed may be referred to as a light-emitting pixel PG, and the light-emitting pixel P in which the blue colored layer 123B is disposed may be referred to as a light-emitting pixel PB.

The light-emitting pixels P of the same color adjacent in the Y direction and the light-emitting pixels P of different colors adjacent in the X direction are electrically insulated by an insulating film 154. A pixel emission region, that is, a pixel emission area of each of the light-emitting pixels PR, PG, and PB is defined by openings 154r, 154g, and 154b disposed in the insulating film 154. The openings 154r, 154g, and 154b in the present exemplary embodiment are rectangles that are long in the Y direction. In the present exemplary embodiment, the openings 154r, 154g, and 154b are formed so that the pixel emission area of each of the light-emitting pixels PR, PG, and PB is the same, but are not limited to this, the openings 154r, 154g, and 154b may have a different size or shape for each color in consideration of hue balance in the display.

The boundary between the colored layer 123R and the colored layer 123G is located between the opening 154r and the opening 154g adjacent in the X direction. The boundary between the colored layer 123G and the colored layer 123B is located between the opening 154g and the opening 154b adjacent in the X direction. Similarly, the boundary between the colored layer 123B and the colored layer 123R is located between the opening 154b and the opening 154r adjacent in the X direction.

The color filter 123 is configured to include a light-transmissive CF partition wall 123a disposed at a position overlapping with an end part in the X direction of each of the colored layers 123R, 123G, and 123B extending in a stripe shape in the Y direction. Next, a detailed structure of the light-emitting pixel P including the color filter 123 in the light emission panel 110 will be described.

Structure of Light-Emitting Panel

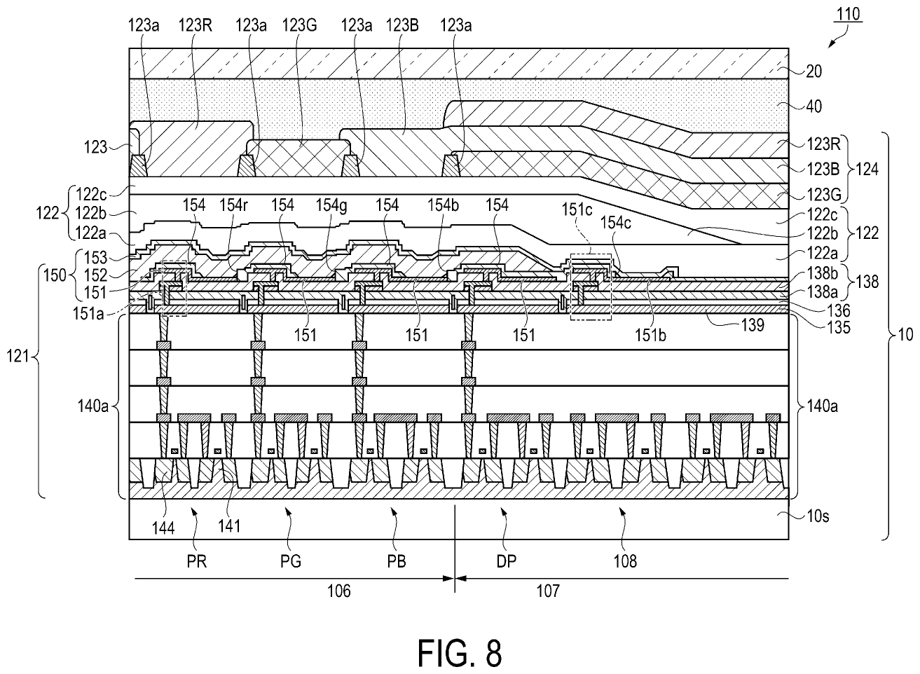

Next, a structure of the light-emitting panel 110 of the light-emitting device 100 will be described with reference to FIG. 8. FIG. 8 is a schematic cross-sectional view illustrating the structure of the light-emitting panel. Note that FIG. 8 is a schematic cross-sectional view cut along the line A-A′, of a quadrangular region C surrounded by a double dot dash line in the display unit 105 illustrated in FIG. 1. Note that the line A-A′ illustrated in FIG. 1 is a line segment crossing the center of the light-emitting portion 106 of the light-emitting device 100 in the X direction.

As illustrated in FIG. 8, the light-emitting panel 110 includes the element substrate 10 and the light-transmissive counter substrate 20 that are attached via the light-transmissive filler 40. As described above, a semiconductor substrate such as a silicon substrate is used as a base material 10s of the element substrate 10. The light-emitting element 150 and a circuit unit 140a including various types of transistors and storage capacitors constitute the pixel circuit 140 of the light-emitting pixel P. Note that, in FIG. 8, the first transistor 141 and the fourth transistor 144 are illustrated, and other transistors and storage capacitors are omitted.

The light-emitting element 150 includes the anode 151 as the first electrode, the cathode 153 as the second electrode, and the light-emitting function layer 152 sandwiched between these electrodes. The anode 151 is a transparent electrode, such as Indium Tin Oxide (ITO), and is formed electrically independent of each light-emitting pixels PR, PG, and PB, and the dummy pixels DP.

The light-emitting function layer 152 includes an organic light-emitting layer from which white light is obtained, and is formed over different color light-emitting pixels PR, PG, and PB, and dummy pixels DP. Note that, the configuration of the light-emitting function layer 152 is not particularly limited, but white light can be obtained by combining organic light-emitting layers capable of emitting light of red (R), green (G), and blue (B). Further, a pseudo-white light can be also obtained by combining organic light-emitting layers capable of emitting light of blue (B) and yellow (Y). Further, in addition to the organic light-emitting layer, the light-emitting function layer 152 is configured to include a hole injecting transportation layer disposed on the anode 151 side for efficiently injecting and transporting holes into the organic light-emitting layer, an electron injecting transportation layer disposed on the cathode 153 side for efficiently injecting and transporting electrons to the organic light-emitting layer, and the like.

The cathode 153 is formed from, for example, an alloy of Ag (silver) and Mg (magnesium), which is formed so as to have both light-transmissive and light reflectivity, and is formed over the light-emitting pixels PR, PG, and PB of different colors, the dummy pixels DP, and the cathode contact portion 108.

In the red (R) light-emitting pixel PR, an insulating film 154 is formed so that the opening 154r opens on the anode electrode 151. In the green (G) light-emitting pixel PG, an insulating film 154 is formed so that the opening 154g opens on the anode electrode 151. In the blue (B) light-emitting pixel PB, an insulating film 154 is formed so that the opening 154b opens on the anode electrode 151. On the other hand, in the dummy pixel DP, an insulating film 154 is formed to cover the anode electrode 151. Accordingly, the light-emitting element 150 included in the dummy pixel DP is configured so that no current flows, thus the dummy pixels DP are always in a non-emitting state. Note that, as illustrated in FIG. 6, the number of dummy pixels DP adjacent to the light-emitting pixels P is three in the present exemplary embodiment, but one dummy pixel DP is illustrated in FIG. 8 for convenience of explanation.

An electrode 151b formed by using a transparent conductive film is also disposed in the cathode contact portion 108 formed to imitate the structure of the light-emitting pixel P in the same layer as the anode 151 of the light-emitting element 150. Further, an insulating film 154 is formed so that an opening 154c opens on the electrode 151b. In addition, the cathode 153, which is a common electrode, is formed so as to straddle the cathode contact portion 108. An outer edge of the light-emitting function layer 152 is located between the dummy pixel DP and the cathode contact portion 108. That is, the light-emitting function layer 152 is not formed in the cathode contact portion 108, thus, it is in a state where the electrode 151b and the cathode 153 are shorted at the opening 154c of the cathode contact portion 108. Note that, as illustrated in FIG. 6, the width in the X direction of the cathode contact portion 108 corresponds to two of the light-emitting pixels P, but in the present exemplary embodiment, for convenience of explanation, the cathode contact portion 108 is illustrated as a size corresponding to one of the light-emitting pixels P.

A reflective layer 135, a first insulating film 136, an optical adjusting layer 138, and the like are formed between the anode 151 of each of the light-emitting pixels PR, PG, and PB, and the dummy pixels DP, the electrode 151b of the cathode contact portion 108, and the circuit unit 140a on which the transistor or the like of the pixel circuit 140 is formed. The reflective layer 135, the first insulating film 136, the optical adjusting layer 138, and the like constitute a light resonance structure. A detailed configuration of the light resonance structure will be described later, but the reflective layer 135 is formed electrically independent for each of the light-emitting pixels PR, PG, and PB, and the dummy pixels DP. The anode electrode 151 included in the light-emitting pixels PR, PG, and PB, and the dummy pixels DP is coupled to the fourth transistor 144 of the circuit unit 140a via an anode contact portion 151a that penetrates the optical adjusting layer 138 and the first insulating film 136 to the reflective layer 135. That is, the reflective layer 135 of the light-emitting pixels PR, PG, and PB, and the dummy pixels DP is formed to function as a relay layer for electrical connection between the anode electrode 151 and the fourth transistor 144.

The electrode 151b included in the cathode contact portion 108 is also coupled to the reflective layer 135 via the contact portion 151c that penetrates the optical adjusting layer 138 and the first insulating film 136. The reflective layer 135 in this case is formed so as to function as part of the cathode wiring 139 (see FIG. 4) to which the cathode potential VCT is supplied.

A sealing film 122 is formed so as to cover the element portion 121 including the circuit unit 140a and the light-emitting element 150 of the pixel circuit 140, the dummy pixels DP, and the cathode contact portion 108. The sealing film 122 is configured to include a first sealing film 122a made of an inorganic film formed at least over the display unit 105, an intermediate sealing film 122b made of an organic film formed to alleviate irregularities in the surface of the first sealing film 122a, and a second sealing film 122c made of an inorganic film formed to cover the intermediate sealing film 122b. The intermediate sealing film 122b is formed so as to overlap with the light-emitting pixels PR, PG, and PB, the dummy pixels DP, and the cathode contact portion 108 in a plan view. That is, an outer edge of the intermediate sealing film 122b is located outward the cathode contact portion 108. The first sealing film 122a and the second sealing film 122c made of the inorganic film are stacked outside the outer edge of the intermediate sealing film 122b. In order to prevent moisture, oxygen, or the like from entering into the light-emitting element 150 and deactivating the light-emitting function layer 152, the inorganic is formed by a vapor deposition method or the like, for example, using an oxy nitride film (SiON film) of silicon and the like. The film thickness of the first sealing film 122a constituted by the inorganic film is 400 nm, for example, and the film thickness of the second sealing film 122c is 800 nm, for example. The organic film is formed by a printing method or the like, for example, using an epoxy resin which is excellent in translucency. The film thickness of the intermediate sealing film 122b is 2.6 μm, for example.

In forming the colored layers 123R, 123G, and 123B of the striped color filter 123 on the sealing film 122 in which the surface is in a flat state, a transparent CF partition wall 123a is first formed. The CF partition wall 123a is formed in a stripe shape between light-emitting pixels P of different colors that are adjacent to each other in a plan view by coating a photosensitive resin that does not include a color material for the color filter 123 to form a photosensitive resin layer having a predetermined film thickness, and exposing, developing, and post-baking the photosensitive resin layer. The height (film thickness) of the CF partition wall 123a on the sealing film 122 is less than the thickness of the colored layers 123R, 123G, and 123B formed later. In other words, the colored layers 123R, 123G, and 123B are formed so as to cover the CF partition wall 123a.

The colored layers 123R, 123G, and 123B are formed in a striped shape by coating a photosensitive resin that includes the color material of a corresponding color to form a photosensitive resin layer having a predetermined film thickness, and exposing, developing, and post-baking the photosensitive resin layer. As a method for coating the photosensitive resin including a color material, a spin coating method is used, for example, by forming the CF partition wall 123a in advance, and a structure is formed in which the predetermined film thickness is easily secured in the colored layers 123R, 123G, 123B. In the present exemplary embodiment, the colored layer 123G of green (G), the colored layer 123B of blue (B), and the colored layer 123R of red (R) are formed in this order. The film thicknesses of the colored layers 123R, 123G, 123B are not necessarily the same, and are set in consideration of the transmittance of color light and color purity in display. In the present exemplary embodiment, the average film thickness of the colored layer 123G of green (G) is approximately 1.0 μm, the average film thickness of the colored layer 123B of blue (B) is approximately 1.3 μm, and the average film thickness of the colored layer 123R of red (R) is set to approximately 1.6 μm. That is, the colored layers are formed in ascending order of the film thickness.

In the present exemplary embodiment, the colored layer 123G of green (G), the colored layer 123B of blue (B), and the colored layer 123R of red (R) are layered in this order so as to overlap with the dummy pixels DP and the cathode contact portions 108 in a plan view to form a light shielding portion 124. In the non-light-emitting portion 107 surrounding the light-emitting portion 106, the light shielding portion 124 is formed by overlaying with the colored layers 123R, 123G, and 123R of different color, and light that leaks obliquely from the light-emitting portion 106 is shielded by the non-light-emitting portion 107.

The filler 40 is coated so as to cover the color filter 123, and the light-transmissive counter substrate 20 is adhered to cure the filler 40. The filler 40 is, for example, a thermosetting epoxy resin with a film thickness of approximately 2.0 μm.

Light Resonance Structure

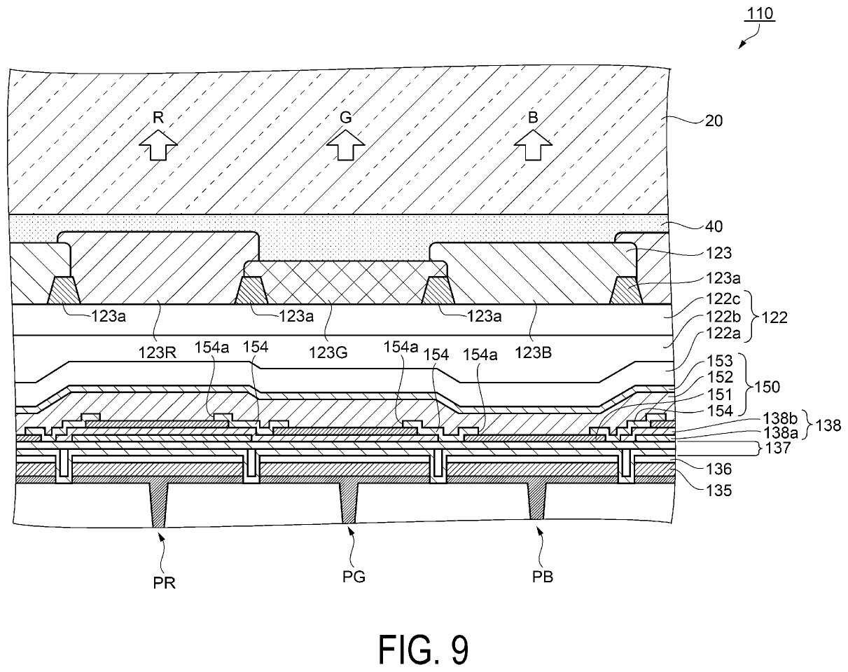

Next, the light resonance structure of the light-emitting panel 110 will be described with reference to FIG. 9. FIG. 9 is an enlarged cross-sectional view illustrating the light resonance structure of the light-emitting pixels of the light-emitting panel.

As described above, the light-emitting panel 110 of the light-emitting device 100 of the present exemplary embodiment is configured to transmit the white light from the light-emitting element 150 through the colored layers 123R, 123G, and 123B of the color filter 123, and extracts the color light of any of red (R), green (G), and blue (B) from the light-emitting pixel P. In addition, from the viewpoint of improving the color purity of the color light, a light resonance structure corresponding to the wavelength of the color light is incorporated in the light-emitting pixel P.

FIG. 9 illustrates the respective light resonance structures of light-emitting pixels PR for which light emission of red (R) is obtained, light-emitting pixels PG for which emission of green (G) is obtained, and light-emitting pixels PB for which emission of blue (B) is obtained.

As illustrated in FIG. 9, a reflective layer 135 is disposed in a lower layer of the transparent anode 151 of each light-emitting pixel PR, PG, and PB. Additionally, the cathode 153 is configured so as to include both light-transmittance and reflectivity. Therefore, light that is emitted from the light-emitting function layer 152 between the anode 151 and the cathode 153 is transmitted through the cathode 153, and is incident on each of the colored layers 123R, 123G, and 123B of the color filter 123 includes light that is transmitted through the anode 151 and reflected by the reflective layer 135, and light that is multiply reflected between the reflective layer 135 and the cathode 153.

In the light-emitting pixels PR, PG, and PB, by varying an optical distance between the reflective layer 135 and the cathode 153, a light resonance is generated between the reflective layer 135 and the cathode 153, and the intensity of light having a specific wavelength is improved in accordance with the color light. The resonant wavelength A as the specific wavelength obtained by light resonance is guided by the following Expression 1:

mλ=2nd+Φ (1)

In Expression 1, m refers to as a dimension of the light resonance with a positive integer (0, 1, 2, . . . ), n is a refractive index of an optical layer between the reflective layer 135 and the cathode 153, d is the film thickness of the optical layer, and Φ is a reflection phase shift. In practice, since there are a plurality of layers between the reflective layer 135 and the cathode 153, the sum of the product of the refractive index and the film thickness of each layer is applied to determine the value of mλ.

Further, in the light-emitting pixels PR, PG, and PB, the film thickness of the anode electrode 151 is equivalent, and the film thickness of the light-emitting function layer 152 between the anode 151 and the cathode 153 is also equivalent. In the present exemplary embodiment, by varying the optical distance between the anode electrode 151 and the reflective layer 135 in the light-emitting pixels PR, PG, and PB, a light resonance corresponding to m=1 in Expression 1 described above is caused. Note that, even in the sealing film 122 and the color filter 123 on the cathode 153, while slight, a reflection is generated at mutual interfaces. The dimensions of the light resonance due to these reflections correspond to m=5 to 10, but considering the refractive index and the film thickness of the optical layer configuring the sealing film 122 and the color filter 123, the light resonance due to these reflections can be substantially neglected.

Specifically, in the light-emitting pixel PR, a first insulating film 136 that covers the reflective layer 135 and functions as a planarization layer, a second insulating film 137 that covers the first insulating film 136 and for electrically independently partitioning the reflective layer 135, a first optical adjusting layer 138a, and a second optical adjusting layer 138b are formed between the reflective layer 135 and the anode 151. The reflective layer 135 is made of, for example, aluminum (Al) which is a light reflective metal, or an alloy including Al. The first insulating film 136 is, for example, a silicon oxide film (SiO₂ film) having a refractive index of 1.46, and the film thickness is 35 nm, for example. The second insulating film 137 is, for example, a silicon nitride film (SiN film) having a refractive index of 1.8, and the film thickness is 50 nm, for example. The first optical adjusting layer 138a and the second optical adjusting layer 138b are, for example, a silicon oxide film (SiO₂ film) having a refractive index of 1.46, and the film thickness is 50 nm, for example. The first optical adjusting layer 138a and the second optical adjusting layer 138b may be collectively and simply referred to as an optical adjusting layer 138. Accordingly, the refractive index of the optical adjusting layer 138 is 1.46, and the film thickness is 100 nm. The anode 151 is formed, for example, using an ITO film with a refractive index of 1.7 to 1.8, such that the film thickness is 20 nm, for example. The light-emitting function layer 152 includes an organic light-emitting layer or the like as described above, but in the present exemplary embodiment, the refractive index is 1.7 to 1.8 and the film thickness is 100 nm, for example. The cathode 153 is, for example, an alloy including silver (Ag) and magnesium (Mg), and is formed so that the film thickness is 20 nm, for example, so as to have light transmittance and light. According to the light resonance structure of the light-emitting pixel PR, resonant light having a resonance wavelength A of approximately 610 nm with improved light intensity due to light resonance is obtained. The color light of red (R) with improved color purity is obtained from the light-emitting pixel PR by transmitting such a resonance light through the colored layer 123R.

In the light-emitting pixel PG, a first insulating film 136, a second insulating film 137, and a second optical adjusting layer 138b are formed between the reflective layer 135 and the anode 151. In other words, compared to the light-emitting pixel PR, the optical distance between the reflective layer 135 and the cathode 153 is reduced by only an amount that the first optical adjusting layer 138a is not formed. According to the light resonance structure of the light-emitting pixel PG, resonant light having a resonance wavelength A of approximately 540 nm with improved light intensity due to light resonance is obtained. The color light of green (G) with improved color purity is obtained from the light-emitting pixels PG by transmitting the colored layer 123G with such a resonant light.

In the light-emitting pixel PB, a first insulating film 136 and a second insulating film 137 are formed between the reflective layer 135 and the anode 151. In other words, compared to the light-emitting pixel PR, the optical distance between the reflective layer 135 and the cathode 153 is reduced by only an amount that the optical adjusting layer 138 is not formed. According to the light resonance structure of the light-emitting pixel PB, resonant light having a resonance wavelength λ of approximately 470 nm with improved light intensity due to light resonance is obtained. The color light of blue (B) with improved color purity is obtained from the light-emitting pixel PB by transmitting the colored layer 123B with the resonant light.

According to the light-emitting device 100 of the first exemplary embodiment, the following effects can be achieved.

(1) The light-emitting panel 110 of the light-emitting device 100 includes a display unit 105 including a circular light-emitting portion 106 in which a plurality of light-emitting pixels P are disposed, and a non-light-emitting portion 107 disposed around the light-emitting portion 106. A data line driving circuit 101 and a scanning line driving circuit 102 for driving the pixel circuit 140 including the light-emitting element 150 in the light-emitting pixel P is disposed in the periphery of the display unit 105. A first data line 131a and a scanning line 132 are disposed in the display unit 105 as driving lines that electrically connect the driving circuit and the pixel circuit 140. The light 106 is circular and the display unit 105 is rectangular, thus, the shorter the length of the part of the driving line disposed in the light-emitting portion 106 is, the longer the length of the part of the driving line disposed in the non-light-emitting portion 107 becomes. In other words, for the driving line across the display unit 105, the length of the driving line disposed in the X direction or the length of the driving line disposed in the Y direction is constant. That is, the circular light-emitting portion 106 includes a portion where the number of light-emitting pixels P attached to the driving line extending in the X direction or the Y direction is different, but the capacitance and the resistance of the driving line are substantially constant, thus, the light-emitting device 100 in which variations in the driving load on the driving line is reduced and the luminance unevenness, that is, the display unevenness between the light-emitting pixels P is unlikely to occur, can be provided.

(2) The cathode contact portion 108 as the second electrode contact portion is disposed with a predetermined number of dummy pixels DP sandwiched between the cathode contact portion 108 and the circular light-emitting portion 106. Therefore, the distance between the light-emitting portion 106 and the cathode contact portion 108 is equidistant, and the wiring resistance from the cathode contact portion 108 to the cathode 153 in the light 106 is made uniform, thus, the luminance unevenness in the light-emitting portion 106 due to variations in the wiring resistance can be further reduced.

(3) The cathode contact portion 108 is formed to imitate the structure of the light-emitting pixels P, and includes an electrode 151b formed in the same layer as the anode 151 of the light-emitting element 150. The electrode 151b is in contact with the cathode 153 at the opening 154c of the insulating film 154 formed on the electrode 151b. Further, the electrode 151b is coupled to the cathode wiring 139 via the contact portion 151c. The cathode electrode potential VCT is applied to cathode wiring 139. Therefore, when forming the anode 151, the electrode 151b that configures the cathode contact portion 108 can be formed, thus the manufacturing process is not complicated, and the light-emitting device 100 having a simple configuration can be provided.

(4) The dummy pixels DP is provided between the outer edge of the light-emitting portion 106 and the cathode contact portion 108. The light-emitting function layer 152 is formed over the circular light-emitting portion 106 and the dummy pixels DP. An outer edge of the light-emitting function layer 152 is located between the dummy pixel DP and the cathode contact portion 108. Thus, in the formation of the light-emitting function layer 152, for example, even if the thickness of the film on the outer edge side of the light-emitting function layer 152 fluctuates, such variation in film thickness can be prevented from affecting the light-emitting portion 106. That is, by providing the dummy pixels DP in the non-light-emitting portion 107, it is possible to make the film thickness of the light-emitting function layer 152 in the light-emitting portion 106 to be uniform, thus the luminance unevenness in the light-emitting portion 106 caused by variations in the film thickness of the light-emitting function layer 152 can be further reduced. In addition, the anode electrode 151 of the light-emitting element 150 in the dummy pixel DP is covered by the insulating film 154, thus, the anode 151 and the light-emitting function layer 152 are isolated and are non-emitting. That is, the configuration is such that light emission is not generated unexpectedly in the non-light-emitting portion 107.

(5) The light-emitting pixel P in the light-emitting portion 106 has a light-emitting element 150 and a colored layer selected from among red (R), green (G), and blue (B) disposed on the sealing film 122 covering the light-emitting element 150. A light shielding portion 124 formed by laminating a plurality of colored layers 123G, 123B, and 123R of a plurality of colors on the sealing film 122 is disposed in the non-light-emitting portion 107 that surrounds the light-emitting portion 106. Therefore, the full color can be displayed in the light-emitting portion 106, and the light-shielding portion 124 is configured using the three-color colored layers 123G, 123B, and 123R, and thus a step of newly forming the light shielding portion 124 is unnecessary. In addition, by disposing the light shielding portion 124 on the sealing film 122, the light shielding portion 124 can be disposed adjacent to the light-emitting element 150. Accordingly, light that leaks to the outside of the light 106 in an oblique direction with respect to the normal direction from the light-emitting pixels P located at the outer edge of the light 106 can be reliably shielded by the light shielding portion 124. That is, a light-emitting device 100 capable of displaying a good-looking color can be provided.

### Second Exemplary Embodiment

Electronic Apparatus

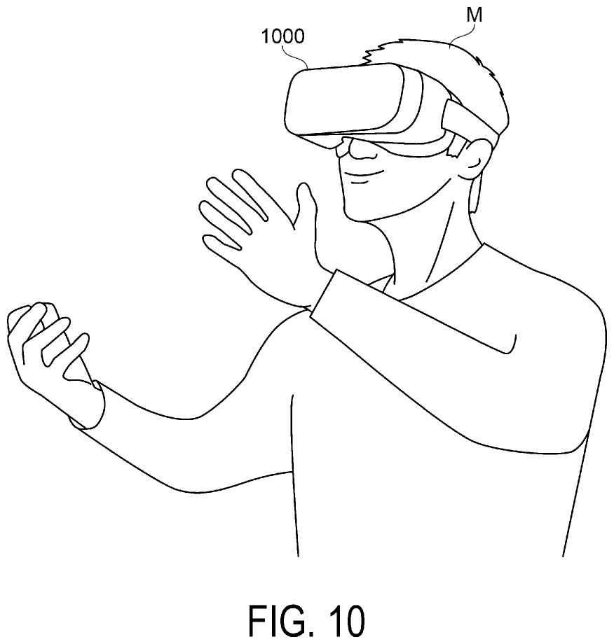

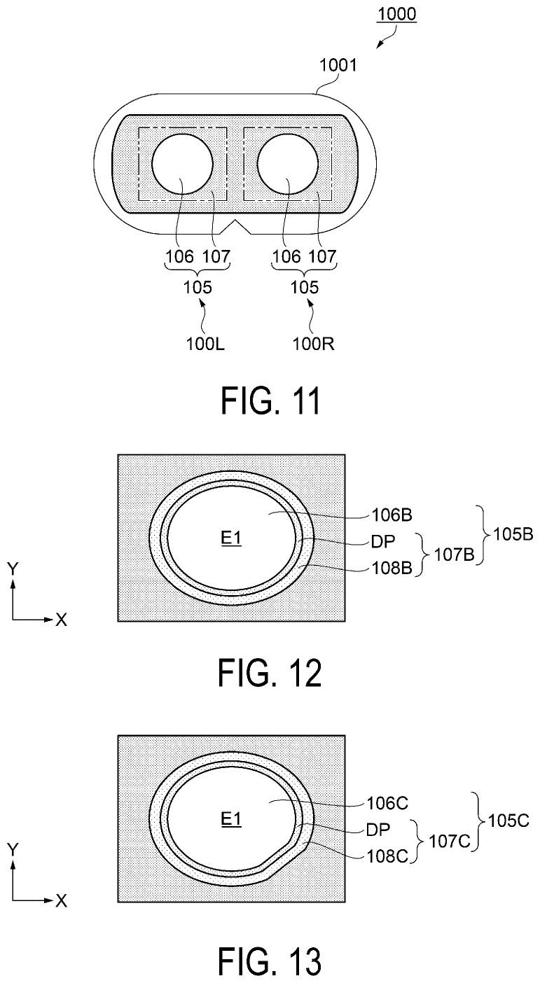

Next, an example of an electronic apparatus to which the light-emitting device 100 of the first embodiment is applied will be described with reference to FIG. 10 and FIG. 11. FIG. 10 is a perspective view illustrating a head-mounted display as an electronic apparatus, and FIG. 11 is a schematic plan view illustrating a configuration of the light-emitting devices in the head-mounted display.

As illustrated in FIG. 10, a head-mounted display (HMD) 1000 as an electronic apparatus of the present exemplary embodiment is a Virtual Reality (VR)-type display system that has a goggle-like form which is worn on head of a user M to cover both eyes and to shield external light, and allows for enjoyment of a displayed virtual reality image, for example.

As illustrated in FIG. 11, the light-emitting device 100 of the first exemplary embodiment is provided respectively as a left eye and a right eye in a hood 1001 that covers both eyes of HMD 1000. Hereinafter, the left eye is referred to as a light-emitting device 100L, and the right eye is referred to as a light-emitting device 100R. When mounted inside the hood 1001, the left and right light-emitting devices 100L and 100R are in a state where the display unit 105 including the non-light-emitting portion 107 other than the light-emitting portion 106 and the peripheral unit are covered by the light shielding member. The light-emitting portion 106 is circular so as to cover the viewing angle range corresponding to the left eye and the right eye.

The HMD 1000 includes a controller (not illustrated) for causing an image to be displayed on each of the left and right light-emitting devices 100L and 100R. The controller includes a built-in storage medium for storing images, audio, and the like to be displayed, and is capable of inputting image signals and the like from outside. Further, the controller is also capable of wired or wireless connection to an external network. That is, various image sources can be used to enjoy audio, music, and the like attached to the image.

The HMD 1000 of the present exemplary embodiment includes a pair of light-emitting devices 100L and 100R corresponding to the left eye and the right eye, and in the light-emitting portion 106, luminance unevenness in the light-emitting pixel P is reduced, and a good-looking display is possible. Further, light leakage from the non-light-emitting portion 107 other than the light-emitting portion 106 is prevented. Thus, by mounting the HMD 1000, the user M can become immersed in and view the image displayed in the light-emitting portion 106.

Note that, the human has an angle of view range of approximately 150 degrees in the horizontal direction and approximately 130 degrees in the vertical direction, thus, in order to ensure immersion, the image may be visible in an angle range of not less than 100 degrees in the horizontal direction and the vertical direction, respectively. Accordingly, in order to make the image in the light-emitting portion 106 visible in an angular range of not less than 100 degrees, the size of the light-emitting portion 106 may be adjusted, or an optical element such as a lens corresponding to each of the left and right light-emitting portions 106 may be disposed.

Note that, the present disclosure is not limited to the exemplary embodiments described above, and various modifications and improvements can be added to the above-described embodiments. Such modified examples are described below.

### Modified Example 1

The outline of the light-emitting portion 106 in the light-emitting device 100 is not limited to being circular. FIG. 12 to FIG. 14 are schematic plan views illustrating a display unit of a modified example of the light-emitting device.

For example, as illustrated in FIG. 12, the display unit 105B includes a light-emitting portion 106B including an elliptical light-emitting region E1, and a non-light-emitting portion 107B that surrounds the light-emitting portion 106B. The non-light-emitting portion 107B includes dummy pixels DP disposed along the light-emitting portion 106B, and a cathode contact portion 108B disposed around the light-emitting portion 106B with the dummy pixels DP interposed between the cathode contact portion 108B and the light-emitting portion 106B.

Further, the outlines of the light-emitting portion 106 may not be all curved. For example, as illustrated in FIG. 13, a display unit 105C of the modified example includes a light-emitting portion 106C having an elliptical light-emitting region E1 including a linear portion in a part thereof, and a non-light-emitting portion 107C that surrounds the light-emitting portion 106C. The non-light-emitting portion 107C includes dummy pixels DP disposed along the light-emitting portion 106C, and a cathode contact portion 108C disposed around the light-emitting portion 106C with the dummy pixels DP interposed between the cathode contact portion 108C and the light-emitting portion 106C. In this case, the light-emitting portion 106C has a linear shape in which the lower right side is inclined obliquely in a plan view. This is the display unit 105C corresponding to the light-emitting device 100L for the left eye when mounted on the HMD 1000. In the light-emitting device 100R for the right eye, the light-emitting portion 106C may be formed in a linear shape in which the lower left side inclined obliquely in a plan view. That is, when the light-emitting portion 106 is enlarged corresponding to both eyes, the field of view of the user M on the nose side is considered to be substantially limited, so the light-emitting portion 106C having a corresponding shape is considered.

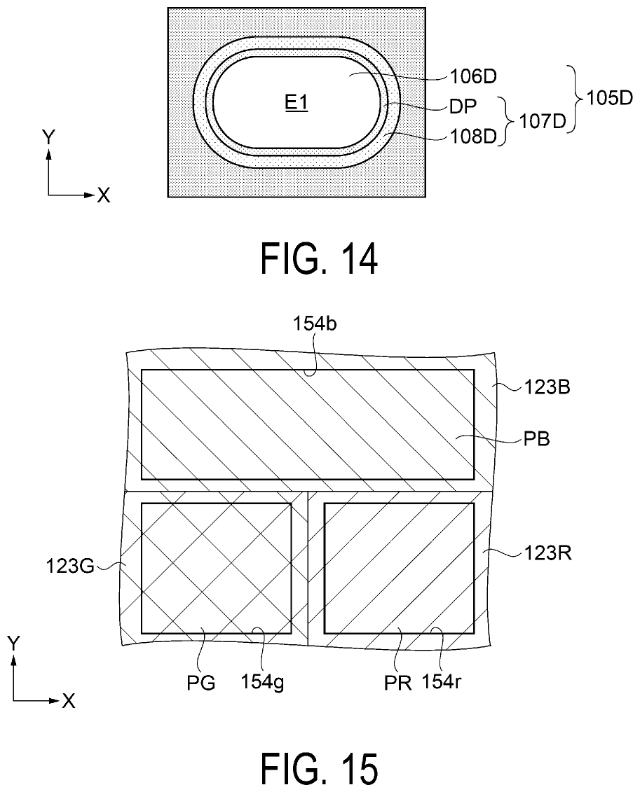

Further, as illustrated in FIG. 14, a display unit 105D of the modified example includes a light-emitting portion 106D having a track-like light-emitting region E1, and a non-light-emitting portion 107D that surrounds the light-emitting portion 106D. The non-light-emitting portion 107D includes dummy pixels DP disposed along the light-emitting portion 106D, and a cathode contact portion 108D disposed around the light-emitting portion 106D with the dummy pixels DP interposed between the cathode contact portion 108D and the light-emitting portion 106D. According to this, the viewing angle range in the horizontal direction (left-right direction) can be further enlarged in comparison to the light-emitting portion 106B illustrated in FIG. 12 and the light-emitting portion 106C illustrated in FIG. 13.

Note that the outline of the light 106 is not limited to a circular shape, an elliptical shape, an elliptical shape in which a part is linear, or a track shape, and may be a polygon having a pentagonal shape or more. Alternatively, it may be cross-shaped or star shaped.

### Modified Example 2

The configuration of the light-emitting pixels PR, PG, and PB from which red (R), green (G), and blue (B) emission are obtained, in other words, the configuration of the color filter 123 corresponding to the light-emitting pixels PR, PG, and PB is not limited to being striped. FIG. 15 is a schematic plan view illustrating a configuration of light-emitting pixels of a modified example. As illustrated in FIG. 15, a display unit pixel of the modified example is configured by, for example, a light-emitting pixel PG of green (G) and a light emitting pixel PR of red (R) disposed so as to be adjacent to each other in the X direction, and a light-emitting pixel PB of blue (B) disposed so as to be adjacent to the light-emitting pixels PG and PR in the Y direction. A colored layer 123B of blue (B) is disposed in the light-emitting pixel PB, a colored layer 123G of green (G) is disposed in the light-emitting pixel PG, and a red (R) colored layer 123 R is disposed in the light-emitting pixel PR. A pixel emission region (in other words, the pixel emission area) of the light-emitting pixel PB is defined by an opening 154b disposed in the insulating film 154. Similarly, the pixel emission region in the light-emitting pixel PG is defined by an opening 154g disposed in the insulating film 154, and the pixel emission region in the light-emitting pixel PR is defined by an opening 154r provided in the insulating film 154. The shape of the display unit pixel in which the light-emitting pixels PR, PG, PB are combined is square, and the pixel emission area of the light-emitting pixel PB of blue (B) having a smaller luminous sensitivity than the other colors is the largest. According to this configuration of the light-emitting pixels PR, PG, and PB, compared to a case where the respective pixel light-emitting area is the same, the display unit pixel can have brightness and hue balance adjusted in the display.

Note that the light-emitting pixel PG of green (G) and the light-emitting pixel PR of red (R) may be disposed so as to be adjacent to each other in the Y direction, and the light-emitting pixel PB of blue (B) may be disposed so as to be adjacent to them in the X direction. In either case, only the colored layer 123B of blue (B) is in a striped configuration.

Further, the light-emitting pixels P included in the display unit pixels are not limited to three primary colors: red (R), green (G), and blue (B), and may be configured by four color light-emitting pixels P including a color other than the three primary colors, for example, a yellow color (Y).

### Modified Example 3

In the light-emitting device 100 of the first exemplary embodiment, one light-emitting portion 106 is disposed in the display unit 105, but the present disclosure is not limited to this. For example, when the light-emitting device 100 is applied to the HMD 1000 of the second exemplary embodiment, the display unit 105 may be configured to include two light-emitting portions 106 corresponding to the left eye and the right eye.

### Fourth Modified Example

The electronic apparatus to which the light-emitting device 100 of the first embodiment is applied is not limited to the HMD 1000 of the second exemplary embodiment. For example, a light-emitting device 100 may be used as a display device for a personal digital assistant that is mounted on an arm.

Contents derived from the exemplary embodiments will be described below.

The light-emitting device of the present application includes a light-emitting portion in which a light-emitting pixel is disposed, a non-light-emitting portion disposed around the light-emitting portion, a driving circuit configured to drive the light-emitting pixel, and a driving line which is disposed in a display unit including the light-emitting portion and the non-light-emitting portion, and which is coupled to the driving circuit, wherein an outline of the light-emitting portion is a shape different from a rectangle, and an outline of the display unit is a rectangle.

According to the configuration of the present application, the outline of the light-emitting portion is a shape different from a rectangle, thus, the number of the light-emitting pixels attached to the driving line varies depending on the position of the driving line in the light-emitting portion. On the other hand, since the outline of the display unit is rectangular, the length of the driving line disposed along the short side or the long side of the display unit can be made constant, thus, even if the number of the light-emitting pixels attached to the driving line varies, the capacitance and the resistance of the driving line can be made substantially constant. That is, even if the outline of the light-emitting portion is different from the rectangle, for example, a shape such as a circle, it is possible to provide a light-emitting device that reduces variation in the drive load related to the driving line and does not cause luminance unevenness, that is, display unevenness between the light-emitting pixels.

The other light-emitting device of the present application includes a light-emitting portion in which a light-emitting pixel is disposed, a non-light-emitting portion disposed around the light-emitting portion, and a driving line which is disposed in a display unit including the light-emitting portion and the non-light-emitting portion, and which is related to the light-emitting pixel, wherein an outline of the light-emitting portion is a shape different from a rectangle, and the shorter a part of the driving line disposed in the light-emitting portion is, the longer a part of the driving line disposed in the non-light-emitting portion is.

According to the configuration of the present application, the outline of the light-emitting portion is a shape different from a rectangle, thus, the number of the light-emitting pixels attached to the driving line varies depending on the position of the driving line in the light-emitting portion. On the other hand, the shorter the part of the driving line disposed in the light-emitting portion is, the longer the part of the driving line disposed in the non-light-emitting portion is, thus the length of the driving line disposed across the display unit can be constant. That is, even if the number of the light-emitting pixels attached to the driving line varies, the capacitance and resistance of the driving line can be made substantially constant. That is, even if the outline of the light-emitting portion is different from the rectangle, for example, a shape such as a circle, it is possible to provide a light-emitting device that reduces variation in the drive load related to the driving line and does not cause luminance unevenness, that is, display unevenness between the light-emitting pixels.

In the light-emitting device described above, the light-emitting pixel includes a first electrode and a second electrode, and a light-emitting function layer disposed between the first electrode and the second electrode, the second electrode is a common electrode disposed over the light-emitting portion and the non-light-emitting portion, and the non-light-emitting portion includes a second electrode contact portion disposed along the outline of the light-emitting portion.

According to this configuration, the second electrode contact portion is disposed along the outline of the light-emitting portion, and variations in the potential supplied to the second electrode serving as a common electrode in the light-emitting portion via the second electrode contact portion can be reduced. That is, the luminance unevenness in the light-emitting portion caused by the variation in the potential can be reduced.

In the light-emitting device described above, the second electrode contact portion may be disposed equidistantly from an outer edge of the light-emitting portion.

According to this configuration, wiring resistance from the second electrode contact portion to the second electrode is made uniform, thus the luminance unevenness in the light-emitting portion due to variations in the wiring resistance can be further reduced.

In the light-emitting device described above, the second electrode contact portion may include an electrode disposed in the same layer as the first electrode, and the electrode and the second electrode may be in contact with each other by the second electrode contact portion.

According to this configuration, when forming the first electrode, the electrode constituting the second electrode contact portion can be formed, thus, the manufacturing process is not complicated, and a light-emitting device having a simple configuration can be provided.

In the light-emitting device described above, the light-emitting function layer may be formed over the light-emitting portion and the non-light-emitting portion, and an outer edge of the light-emitting function layer may be located between an outer edge of the light-emitting portion and the second electrode contact portion.

According to this configuration, the occurrence of unexpected emission from the light-emitting function layer in the non-light-emitting portion can be reduced.

In the light emitting device described above, the non-light-emitting portion may include a non-light-emitting dummy pixel between an outer edge of the light-emitting portion and the second electrode contact portion.

According to this configuration, even in a case where the thickness of the film on the outer edge side of the light-emitting function layer fluctuates in the formation of the light-emitting function layer, such variation in film thickness can be prevented from affecting the light-emitting portion. That is, by providing the dummy pixels in the non-light-emitting portion, it is possible to make the film thickness of the light-emitting function layer in the light-emitting portion to be uniform, thus the luminance unevenness in the light-emitting portion caused by variations in the film thickness of the light-emitting function layer can be further reduced.

In the light emitting device described above, the dummy pixel may include the first electrode, the second electrode, and the light-emitting function layer, similar to the light-emitting pixel, and the dummy pixel may include an insulating film between the first electrode and the light-emitting function layer.

This configuration may prevent unexpected emission in the dummy pixels.

In the light emitting device described above, the light emitting device may include a sealing film disposed on the display unit and covering at least the light-emitting portion and the second electrode contact portion, and a color filter disposed corresponding to the light-emitting pixel on the sealing film.

According to this configuration, a light-emitting device capable of displaying full color in the light-emitting portion, and in which display unevenness is unlikely to occur can be provided.

An electronic apparatus according to the present disclosure includes the light-emitting device described above.

According to the configuration of the present application, the display unevenness is unlikely to occur, and an electronic apparatus having excellent display quality can be provided.

What is claimed is:

1. A light-emitting device, comprising:
a display unit including a light-emitting portion in which a light-emitting pixel is disposed and a non-light-emitting portion disposed around the light-emitting portion;
a driving circuit configured to drive the light-emitting pixel; and
a driving line that is disposed in the display unit and that is coupled to the driving circuit, wherein
an outline of the light-emitting portion is a shape different from a rectangle, and an outline of the display unit is a rectangle.

2. The light-emitting device according to claim 1, wherein
the light-emitting pixel includes
a first electrode and a second electrode, and
a light-emitting function layer disposed between the first electrode and the second electrode,
the second electrode is a common electrode disposed over the light-emitting portion and the non-light-emitting portion, and
the non-light-emitting portion includes a second electrode contact portion disposed along the outline of the light-emitting portion.

3. The light-emitting device according to claim 2, wherein
the second electrode contact portion is disposed equidistantly from an outer edge of the light-emitting portion.

4. The light-emitting device according to claim 2, wherein
the second electrode contact portion includes an electrode disposed in the same layer as the first electrode, and
the electrode and the second electrode are in contact with each other via the second electrode contact portion.

5. The light-emitting device according to claim 2, wherein
the light-emitting function layer is formed over the light-emitting portion and the non-light-emitting portion, and
an outer edge of the light-emitting function layer is located between the second electrode contact portion and an outer edge of the light-emitting portion.

6. The light-emitting device according to claim 2, wherein
the non-light-emitting portion includes a non-light-emitting dummy pixel between the second electrode contact portion and an outer edge of the light-emitting portion.

7. The light-emitting device according to claim 6, wherein
the dummy pixel includes
the first electrode,
the second electrode, and
the light-emitting function layer and
the dummy pixel includes an insulating film between the first electrode and the light-emitting function layer.

8. The light-emitting device according to claim 2, comprising:
a sealing film disposed on the display unit and covering at least the light-emitting portion and the second electrode contact portion; and
a color filter disposed, on the sealing film, corresponding to the light-emitting pixel.

9. A light-emitting device, comprising:
a display unit including a light-emitting portion in which a light-emitting pixel is disposed and a non-light-emitting portion disposed around the light-emitting portion; and
a driving line that is disposed in the display unit and that is related to the light-emitting pixel, wherein
an outline of the light-emitting portion is a shape different from a rectangle, and the shorter a part of the driving line disposed in the light-emitting portion is, the longer a part of the driving line disposed in the non-light-emitting portion is.

10. The light-emitting device according to claim 9, wherein
the light-emitting pixel includes
a first electrode and a second electrode, and
a light-emitting function layer disposed between the first electrode and the second electrode,
the second electrode is a common electrode disposed over the light-emitting portion and the non-light-emitting portion, and
the non-light-emitting portion includes a second electrode contact portion disposed along the outline of the light-emitting portion.

11. The light-emitting device according to claim 10, wherein
the second electrode contact portion is disposed equidistantly from an outer edge of the light-emitting portion.

12. The light-emitting device according to claim 10, wherein
the second electrode contact portion includes an electrode disposed in the same layer as the first electrode, and
the electrode and the second electrode are in contact with each other via the second electrode contact portion.

13. The light-emitting device according to claim 10, wherein
the light-emitting function layer is formed over the light-emitting portion and the non-light-emitting portion, and
an outer edge of the light-emitting function layer is located between the second electrode contact portion and an outer edge of the light-emitting portion.

14. The light-emitting device according to claim 10, wherein
the non-light-emitting portion includes a non-light-emitting dummy pixel between the second electrode contact portion and an outer edge of the light-emitting portion.

15. The light-emitting device according to claim 14, wherein
the dummy pixel includes
the first electrode,
the second electrode, and
the light-emitting function layer and
the dummy pixel includes an insulating film between the first electrode and the light-emitting function layer.

16. The light-emitting device according to claim 10, comprising:
a sealing film disposed on the display unit and covering at least the light-emitting portion and the second electrode contact portion; and
a color filter disposed, on the sealing film, corresponding to the light-emitting pixel.

17. An electronic apparatus comprising:
the light-emitting device according to claim 1.

18. An electronic apparatus comprising:
the light-emitting device according to claim 9.
